(19) United States
(12) Patent Application Publication
(10) Pub. No.: US 2026/0282510 A1
(43) Pub. Date: Sep. 17, 2026

(54) GATE STRUCTURES FOR MULTI-GATE TRANSISTORS

(71) Applicant: Taiwan Semiconductor Manufacturing Company, Ltd., Hsin-Chu (TW)

(72) Inventors: Chih-Wei LEE, New Taipei City (TW); Yi-Lun LI, Hsinchu (TW); Hsuan-Yu Tung, Keelung (TW); Hsin-Han Tsai, Hsinchu (TW)

(21) Appl. No.: 19/266,578

(22) Filed: Jul. 11, 2025

Related U.S. Application Data
(60) Provisional application No. 63/772,111, filed on Mar. 14, 2025.

(51) Int. Cl. H10D 84/01; H10D 84/85

(52) U.S. Cl. CPC H10D 84/0177; H10D 84/851

(57) ABSTRACT

A method for forming a gate structure according to the present disclosure includes receiving a precursor structure that includes a substrate, first nanostructures over a first region of the substrate, and second of nanostructures over a second region of the substrate, depositing a gate dielectric layer over the first nanostructures and the second nanostructures, depositing a first work function metal layer over the first nanostructures and the second nanostructures, depositing a diffusion blocking layer over the first work function metal layer, selectively removing the diffusion blocking layer and the first work function metal layer from the first nanostructures over the first region, depositing a second work function metal layer over the first nanostructures and the second nanostructures, and depositing a metal fill layer over the second work function metal layer.

### PRIORITY DATA

This application claims priority to U.S. Provisional Patent Application No. 63/772,111, filed on Mar. 14, 2025, which is hereby incorporated herein by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate devices have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors (both also referred to as non-planar transistors) are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). Compared to planar transistors, such configuration provides better control of the channel and drastically reduces SCEs (in particular, by reducing sub-threshold leakage (i.e., coupling between a source and a drain of the FinFET in the “off” state)). A GAA transistor has a gate structure that can extend, partially or fully, around a channel region to provide access to the channel region on two or more sides. Due to this configuration, a GAA transistor may also be referred to as a surrounding-gate transistor (SGT) or a multi-bridge-channel (MBC) transistor. The channel region of the GAA transistor may be formed from nanowires, nanosheets, other nanostructures, and/or other suitable structures. These shapes of the channel region also give a GAA transistor different names. For example, a GAA transistor with nanosheet channel regions may be referred to as a nanosheet transistor.

FinFETs have been the predominant choice of transistors when high performance computing is desired. GAA transistors may ultimately replace FinFETs because they may provide improved channel control and enabling further miniaturization. Formation of GAA transistors brings challenges.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIG. 1 is a flowchart illustrating a method of forming a semiconductor device according to various aspects of the present disclosure.

FIGS. 2-19 illustrate fragmentary cross-sectional views of a first area and a second area of a precursor structure at various stages of fabrication in accordance with the method in FIG. 1.

FIG. 20 illustrates a fragmentary cross-sectional view along line A-A′ in FIG. 19, according to various aspects of the present disclosure.

FIG. 21 illustrates a fragmentary cross-sectional view along line B-B′ in FIG. 19, according to aspects of the present disclosure.

FIG. 22 illustrates an alternative semiconductive device where a gate structure includes at least one seam, according to various aspects of the present disclosure.

FIG. 23 illustrates diffusivity of aluminum in different materials.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

A GAA transistor has a gate structure that extends, partially or fully, around a channel region to provide access to the channel region on two or more sides. A channel region of a GAA transistor may include multiple sheet-like or wire-like nano-size channel members that are stacked one over another or placed side by side. Formation of GAA transistors comes with its own challenges. For example, without silicon germanium channels to help lower threshold voltage for p-type GAA transistors, work function metal layers having work functions closer to the valence band are needed to keep a low threshold voltage. Diffusion of impurities from an n-type work function metal layer into the p-type work function metal layer may impact performance of the p-type GAA transistor.

The present disclosure relates to formation of gate structures for p-type GAA transistors and n-type GAA transistors on a substrate. A precursor structure that includes first nanostructures over a first region and second nanostructures over a second region. After forming an interfacial layer and a gate dielectric layer over surfaces of the first nanostructures and the second nanostructures, a first work function metal (WFM) layer is deposited over the first region and the second region. After the deposition of the first WFM layer, a diffusion blocking layer is deposited over the first WFM layer. The diffusion blocking layer and the first WFM layer are then selectively removed from the first region to expose the gate dielectric layer. After the selective removal, a second WFM layer is deposited over the first region and the second region. A glue layer and a metal fill are then deposited over the first region and the second region. In some examples, the diffusion blocking layer includes titanium tungsten nitride (TiWN).

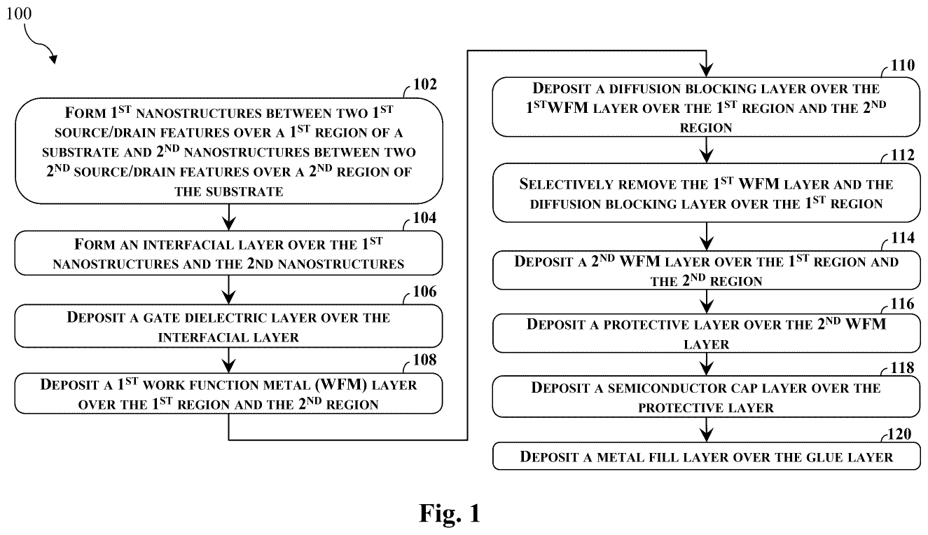

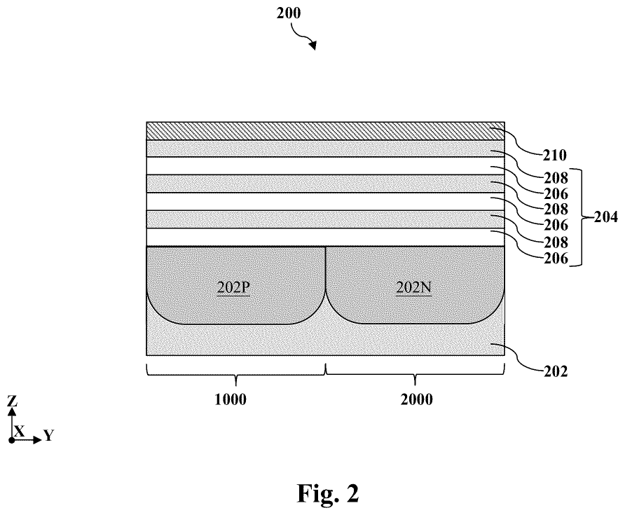

The various aspects of the present disclosure will now be described in more detail with reference to the figures. In that regard, FIG. 1 is a flowchart illustrating method 100 for forming gate structures for a stacked multi-gate device according to various aspects of the present disclosure. Method 100 is merely an example and is not intended to limit the present disclosure to what is explicitly illustrated in method 100. Additional steps may be provided before, during and after method 100 and some steps described can be replaced, eliminated, or moved around for additional embodiments of the method. Not all steps are described herein in detail for reasons of simplicity. Method 100 is described below in conjunction with FIGS. 2-19, which are fragmentary cross-sectional views of a precursor structure 200 at different stages of fabrication according to embodiments of method 100. Because the precursor structure 200 will be fabricated into a semiconductor device 200 upon conclusion of the fabrication processes, the precursor structure 200 may be referred to as the semiconductor device 200 as the context requires. Additionally, throughout the present application and across different embodiments, like reference numerals denote like features with similar structures and compositions, unless otherwise excepted. Source/drain region(s) may refer to a source or a drain, individually or collectively dependent upon the context.

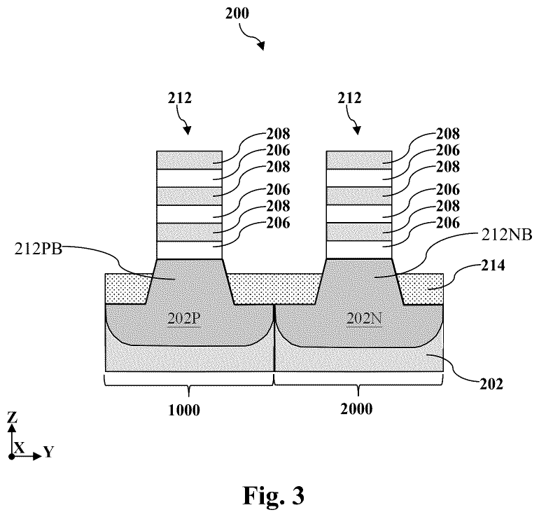

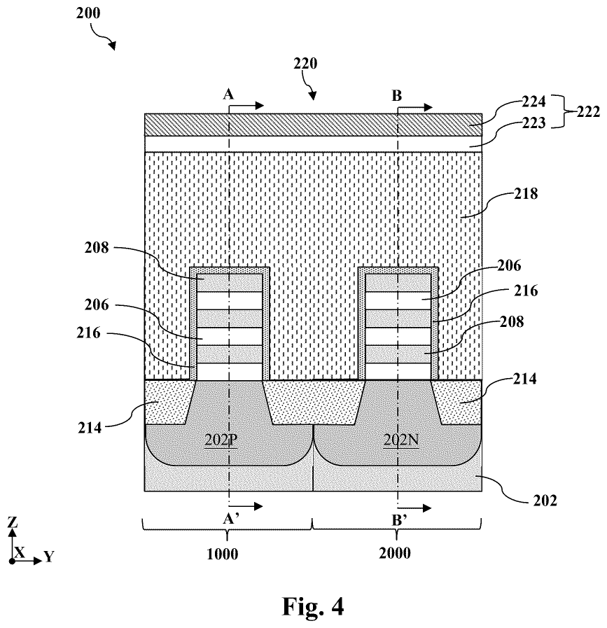

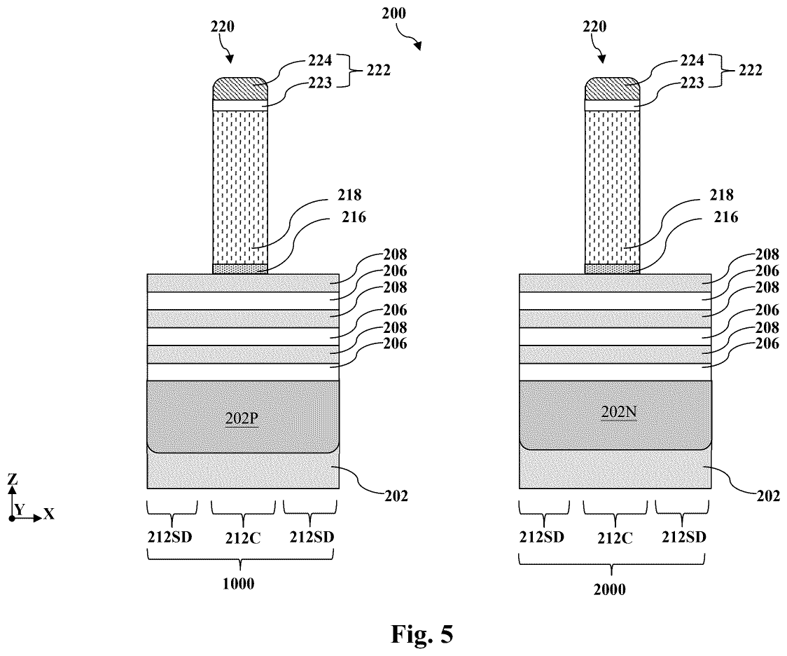

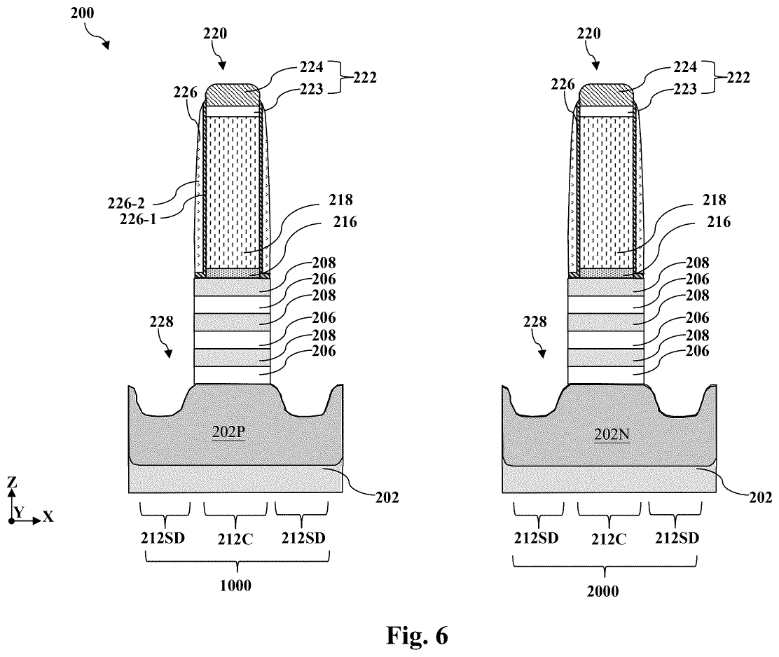

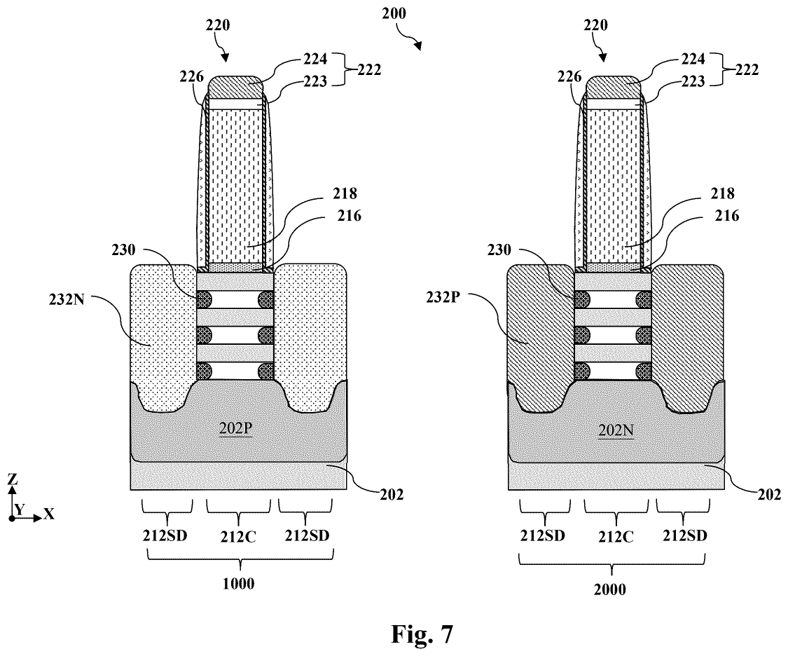

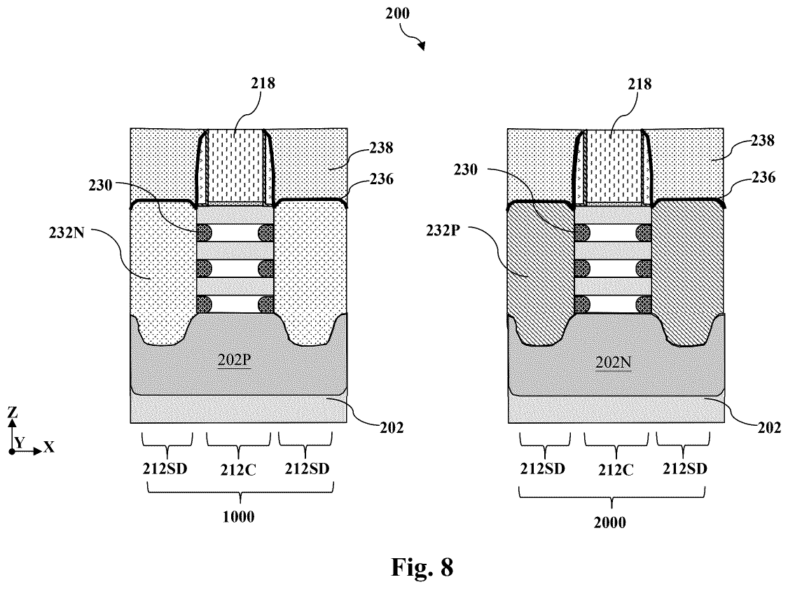

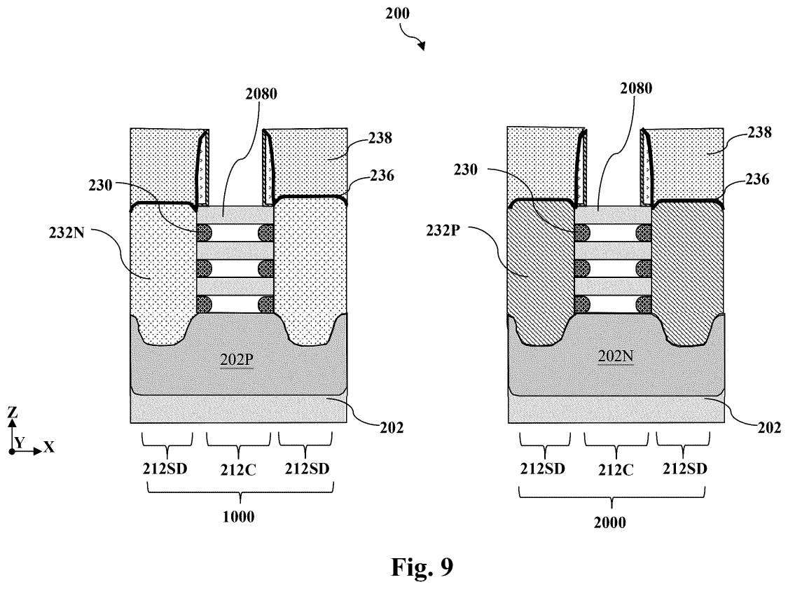

Referring to FIGS. 1-9, method 100 includes a block 102 where first nanostructures 2080 are formed between two first source/drain features 232N over a first region 1000 of a substrate 202 and second nanostructures 2080 are formed between two second source/drain features 232P over a second region 2000 of the substrate 202. Operations at block 102 includes formation of a stack 204 over a substrate 202 (shown in FIG. 2), patterning of the stack 204 and a portion of the substrate 202 to form a fin-shaped structure 212 (shown in FIG. 3), formation of a dummy gate stack 220 over channel regions of the fin-shaped structure 212 (shown in FIGS. 4 and 5), formation of a gate spacer layer 226 and recessing of source/drain regions 212SD of the fin-shaped structure 212 (shown in FIG. 6), formation of first source/drain features 232N and second source/drain features 232P (shown in FIG. 7), deposition of a contact etch stop layer (CESL) 236 and an interlayer dielectric (ILD) layer 238 (shown in FIG. 8), and removal of the dummy gate stack 220 and release of the first nanostructures 2080 and second nanostructures 2080 in the first region 1000 and the second region 2000 (shown in FIG. 9).

Referring to FIG. 2, the substrate 202 is part of a precursor structure 200 that undergoes the various operations of method 100. In some embodiments, the substrate 202 may be a semiconductor substrate such as a silicon (Si) substrate. The substrate 202 may also include other semiconductors such as germanium (Ge), silicon carbide (SiC), silicon germanium (SiGe), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features. The substrate 202 may include various doping configurations depending on design requirements as is known in the art. In the depicted embodiments, the substrate 202 includes a first region 1000 and a second region 2000. The substrate 202 includes a p-type well 202P (i.e., a p-type dopant profile) over the first region 1000 and an n-type well 202N (i.e., an n-type doping profile) over the second region 2000. In some implementations, the n-type dopant for forming the n-type well 202N may include phosphorus (P) or arsenic (As) and the p-type dopant for forming the p-type well 202P may include boron (B). The suitable doping for the n-type well 202N or the p-type well 202P may include ion implantation of dopants and/or diffusion processes.

Referring still to FIG. 2, the stack 204 includes sacrificial layers 206 of a first semiconductor composition interleaved by channel layers 208 of a second semiconductor composition. The first and second semiconductor compositions may be different. In some embodiments, the sacrificial layers 206 include silicon germanium (SiGe) and the channel layers 208 include silicon (Si). It is noted that three (3) layers of the sacrificial layers 206 and three (3) layers of the channel layers 208 are alternately arranged as illustrated in FIG. 2, which is for illustrative purposes only and not intended to be limiting beyond what is specifically recited in the claims. It can be appreciated that any number of epitaxial layers may be formed in the stack 204. The number of layers depends on the desired number of channels members for the semiconductor device 200. In some embodiments, the number of channel layers 208 is between 2 and 10.

In some embodiments, all sacrificial layers 206 may have a substantially uniform first thickness between about 5 nm and about 10 nm and all of the channel layers 208 may have a substantially uniform second thickness between about 2 nm and about 8 nm. The first thickness and the second thickness may be identical or different. As described in more detail below, the channel layers 208 or parts thereof may serve as channel member(s) for a subsequently-formed multi-gate device and the thickness of each of the channel layers 208 is chosen based on device performance considerations. The sacrificial layers 206 in channel regions(s) may eventually be removed and serve to define a vertical distance between adjacent channel region(s) for a subsequently-formed multi-gate device and the thickness of each of the sacrificial layers 206 is chosen based on device performance considerations.

The layers in the stack 204 may be deposited using a molecular beam epitaxy (MBE) process, a vapor phase deposition (VPE) process, and/or other suitable epitaxial growth processes at a temperature between about 600° C. and about 800° C. As stated above, in at least some examples, the sacrificial layers 206 include an epitaxially grown silicon germanium (SiGe) layer and the channel layers 208 include an epitaxially grown silicon (Si) layer. In some embodiments, the sacrificial layers 206 and the channel layers 208 are substantially dopant-free (i.e., having an extrinsic dopant concentration from about 0 cm⁻³ to about 1×10¹⁷ cm⁻³), where for example, no intentional doping is performed during the epitaxial growth processes for the stack 204.

Referring FIG. 3, a fin-shaped structure 212 is formed from the stack 204 and a portion of the substrate 202. To pattern the stack 204, a hard mask layer 210 (shown in FIG. 2) may be deposited over the stack 204 to form an etch mask. The hard mask layer 210 may be a single layer or a multi-layer. For example, the hard mask layer 210 may include a pad oxide layer and a pad nitride layer over the pad oxide layer. The fin-shaped structure 212 may be patterned from the stack 204 and a portion of the substrate 202 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods. As shown in FIG. 3, the etch process forms trenches extending through the stack 204 and a portion of the substrate 202. The trenches define the fin-shaped structures 212, including base fins (first base fin 212PB and a second base fin 212NB are shown in FIG. 3) formed from the substrate 202. In some implementations, double-patterning or multi-patterning processes may be used to define fin-shaped structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shaped structure 212 by etching the stack 204 and a portion of the substrate 202. As shown in FIG. 3, the fin-shaped structure 212, along with the sacrificial layers 206 and the channel layers 208 therein, extends vertically along the Z direction and lengthwise along the X direction.

An isolation feature 214 is formed adjacent the fin-shaped structure 212. In some embodiments, the isolation feature 214 may be formed in the trenches to isolate the fin-shaped structures 212 from a neighboring active region, which may be another fin-shaped structure. The isolation feature 214 may also be referred to as a shallow trench isolation (STI) feature 214. By way of example, in some embodiments, a dielectric layer is first deposited over the substrate 202, filling the trenches with the dielectric layer. In some embodiments, the dielectric layer may include silicon oxide, silicon nitride, silicon oxynitride, fluorine-doped silicate glass (FSG), a low-k dielectric, combinations thereof, and/or other suitable materials. In various examples, the dielectric layer may be deposited by a CVD process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the STI feature 214. As shown in FIG. 3, a lower portion of the first base fin 212PB and a lower portion of the second base fin 212NB are disposed in or surrounded by the STI feature 214, the rest of the fin-shaped structure 212 that is formed from the stack 204 rises above the STI feature 214 after the recessing. Upper portions of the first base fin 212PB and the second base fin 212NB also rise above the STI feature 214.

Reference is now made to FIGS. 4 and 5. A dummy gate stack 220 is formed over a channel region 212C of the fin-shaped structure 212. In some embodiments, a gate replacement process (or gate-last process) is adopted where the dummy gate stack 220 serves as a placeholder to undergo various processes and is to be removed and replaced by the functional gate structure. Other processes and configuration are possible. In some embodiments illustrated in FIG. 5, the dummy gate stack 220 is formed over the fin-shaped structure 212 and the fin-shaped structure 212 in the first region 1000 and the second region 2000 may be each divided into channel regions 212C underlying the dummy gate stacks 220 and source/drain regions 212SD that do not underlie the dummy gate stacks 220. The channel regions 212C are adjacent the source/drain regions 212SD. As shown in FIG. 5, the channel region 212C is disposed between two source/drain regions 212SD along the X direction.

The formation of the dummy gate stack 220 may include deposition of layers in the dummy gate stack 220 and patterning of these layers. Referring to FIG. 4, a dummy dielectric layer 216, a dummy electrode layer 218, and a gate-top hard mask layer 222 may be deposited over the precursor structure 200. In some embodiments, the dummy dielectric layer 216 may be formed on the fin-shaped structure 212 using a chemical vapor deposition (CVD) process, an ALD process, an oxygen plasma oxidation process, a thermal oxidation process, or other suitable processes. In some instances, the dummy dielectric layer 216 may include silicon oxide. When the dummy dielectric layer 216 is formed using an oxidation process, it may be selectively formed on exposed surfaces of the fin-shaped structure 212, as illustrated in FIG. 4. Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, the gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stack 220, as shown in FIG. 5. For example, the patterning process may include a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods. In some embodiments, the gate-top hard mask layer 222 may include a silicon oxide layer 223 and a silicon nitride layer 224 over the silicon oxide layer 223. As shown in FIG. 5, no dummy gate stack 220 is disposed over the source/drain region 212SD of the fin-shaped structure 212.

Referring now to FIG. 6, at least one gate spacer layer 226 is deposited over the dummy gate stack 220 in the first region 1000 and the second region 2000. In some embodiments, the at least one gate spacer layer 226 is deposited conformally over the precursor structure 200, including over top surfaces and sidewalls of the dummy gate stack 220. The term “conformally” may be used herein for ease of description of a layer having substantially uniform thickness over various regions. The at least one gate spacer layer 226 may be a single layer or a multi-layer. In the depicted embodiments, the at least one gate spacer layer 226 includes a first spacer layer 226-1 and a second spacer layer 226-2 disposed over the first spacer layer 226-1. A composition of the first spacer layer 226-1 may be different from a composition of the second spacer layer 226-2. In some implementation, a dielectric constant of the first spacer layer 226-1 is greater than a dielectric constant of the second spacer layer 226-2. The at least one gate spacer layer 226, including the first spacer layer 226-1 and the second spacer layer 226-2, may include silicon oxide, silicon carbonitride, silicon oxycarbide, silicon oxycarbonitride, or silicon nitride. The at least one gate spacer layer 226 may be deposited over the dummy gate stack 220 using processes such as, a CVD process, a subatmospheric CVD (SACVD) process, an ALD process, or other suitable process. For ease of reference, the at least one gate spacer layer 226 may also be referred to the gate spacer layer 226 for simplicity.

Referring still to FIG. 6, source/drain regions 212SD of the fin-shaped structure 212 are recessed to form source/drain trenches 228. In some embodiments, the source/drain regions 212SD that are not covered by the dummy gate stack 220 and the gate spacer layer 226 are etched by a dry etch or a suitable etching process to form the source/drain trenches 228. For example, the dry etch process may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. In some embodiments represented in FIG. 6, the source/drain regions 212SD of the fin-shaped structure 212 are recessed to expose sidewalls of the sacrificial layers 206 and the channel layers 208. In some implementations, the source/drain trenches 228 extend below the stack 204 into the substrate 202.

Referring to FIG. 7, inner spacer features 230 are formed. After the formation of the source/drain trenches 228, the sacrificial layers 206 in the channel regions 212C are selectively and partially recessed to form inner spacer recesses, while the exposed channel layers 208 are substantially unetched. In an embodiment where the channel layers 208 consist essentially of silicon (Si) and sacrificial layers 206 consist essentially of silicon germanium (SiGe), the selective and partial recess of the sacrificial layers 206 may include a SiGe oxidation process followed by a SiGe oxide removal. In that embodiment, the SiGe oxidation process may include use of ozone (O₃). In some other embodiments, the selective recess may be a selective isotropic etching process (e.g., a selective dry etching process or a selective wet etching process), and the extent at which the sacrificial layers 206 are recessed is controlled by duration of the etching process. The selective dry etching process may include use of one or more fluorine-based etchants, such as fluorine gas or hydrofluorocarbons. The selective wet etching process may include an APM etch (e.g., ammonia hydroxide-hydrogen peroxide-water mixture). After the formation of the inner spacer recesses, an inner spacer material layer is deposited over the precursor structure 200, including in the inner spacer recesses. The inner spacer material layer may include silicon oxide, silicon nitride, silicon oxycarbide, silicon oxycarbonitride, silicon carbonitride, metal nitride, or a suitable dielectric material and may be deposited using CVD, PECVD, SACVD, ALD or other suitable methods. The deposited inner spacer material layer is then etched back to remove excess inner spacer material layer over the gate spacer layer 226 and sidewalls of the channel layers 208, thereby forming the inner spacer features 230. In some embodiments, the etch back process to form the inner spacer features 230 may be a dry etch process that includes use of an oxygen-containing gas, hydrogen (H₂), nitrogen (N₂), a fluorine-containing gas (e.g., NF₃, CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas (e.g., CF₃I), other suitable gases and/or plasmas, and/or combinations thereof. While not explicitly shown, a cleaning process may be performed after the etch back process to remove native oxide and debris from surfaces of the channel layers 208.

Reference is still made to FIG. 7. First source/drain features 232N are formed over source/drain regions 212SD in the first region 1000 and second source/drain features 232P are formed over source/drain regions 212SD in the second region 2000. Each of the first source/drain features 232N and the second source/drain features 232P may be epitaxially and selectively formed from the exposed sidewalls of the channel layers 208 and exposed surfaces of the substrate 202, while sidewalls of the sacrificial layers 206 remain covered by the inner spacer features 230. Suitable epitaxial processes for formation of the first source/drain features 232N and the second source/drain features 232P include vapor-phase epitaxy (VPE), ultra-high vacuum CVD (UHV-CVD), molecular beam epitaxy (MBE), and/or other suitable processes. The epitaxial growth process may use gaseous precursors, which interact with the composition of the substrate 202 and the channel layers 208. In some embodiments, parameters of the epitaxial growth process are selected such that the first source/drain features 232N and the second source/drain features 232P are not epitaxially deposited on the inner spacer features 230. That said, the overgrowth of the first source/drain features 232N and the second source/drain features 232P may merge over some of the inner spacer feature 230.

The first source/drain features 232N and the second source/drain features 232P may have different conductivity types and may each include more than one epitaxial layers. In some embodiments represented in FIG. 7, the first source/drain features 232N over the first region 1000 may be n-type source/drain features that include silicon (Si) doped with an n-type dopant, such as phosphorus (P) or arsenic (As) and second source/drain features 232P over the second region 2000 may be p-type source/drain features that include silicon germanium (SiGe) doped with a p-type dopant, such as boron (B). When each of the first source/drain features 232N includes multiple epitaxial layers, the epitaxial layer closer to the channel layers 208 and the substrate 202 may include lower n-type dopant concentrations and the epitaxial layer(s) away from the channel layers 208 and the substrate may include higher n-type dopant concentrations. Similarly, when each of the first source/drain features 232N includes multiple epitaxial layers, the epitaxial layer closer to the channel layers 208 and the substrate 202 may include lower p-type dopant concentrations and the epitaxial layer(s) away from the channel layers 208 and the substrate may include higher p-type dopant concentrations. Additionally, when each of the first source/drain features 232N includes multiple epitaxial layers, the epitaxial layer closer to the channel layers 208 and the substrate 202 may include lower germanium (Ge) contents and the epitaxial layer(s) away from the channel layers 208 and the substrate may include higher germanium (Ge) contents. Because the first source/drain features 232N and the second source/drain features 232P have different compositions and are formed in different regions, they are formed separately. In one embodiments, a patterned mask layer, such as a photoresist layer or a bottom antireflective coating (BARC) layer, may be formed to cover the second region 2000, while the first source/drain features 232N are formed in the first region 1000. Then another patterned mask layer may be formed to cover the first region 1000, while the second source/drain features 232P are formed in the second region 2000. In another embodiment, the order may be switched and the second source/drain features 232P are first formed in the second region 2000. While not explicitly shown in the figures, an anneal process may be performed to obtain a desired electronic contribution of the dopant in the semiconductor host, such as silicon germanium (SiGe) or silicon (Si). The anneal process may include a rapid thermal anneal (RTA) process, a laser spike anneal process, a flash anneal process, or a furnace anneal process. The anneal process may include a peak anneal temperature between about 900° C. and about 1000° C. In these implementations, the peak anneal temperature may be maintained for a duration measured by seconds or microseconds.

Referring to FIG. 8, a contact etch stop layer (CESL) 236 and an interlayer dielectric (ILD) layer 238 are deposited over the first source/drain features 232N and the second source/drain features 232P. The CESL 236 may include silicon nitride, silicon oxynitride, and/or other materials known in the art. The ILD layer 238 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, the CESL 236 is first conformally deposited over the first region 1000 and the second region 2000 by CVD, ALD, plasma-enhanced chemical vapor deposition (PECVD) process and/or other suitable deposition or oxidation processes and the ILD layer 238 is deposited over the CESL 236 by spin-on coating, FCVD, CVD, or other suitable deposition technique. In some embodiments, after formation of the ILD layer 238, the precursor structure 200 may be annealed to improve integrity of the ILD layer 238. As shown in FIG. 8, after the deposition of the CESL 236 and the ILD layer 238, a planarization process, such as a chemical mechanical polishing (CMP) process, may be performed to remove excess materials. As shown in FIG. 8, the planarization process also exposes the dummy electrode layer 218 of the dummy gate stacks 220 in the first region 1000 and the second region 2000.

Reference is now made to FIG. 9. The exposed dummy gate stacks 220 are removed and sacrificial layers 206 in the channel regions 210C are selectively removed to release the first nanostructures 2080 in the first region 1000 and the second nanostructures 2080 in the second region 2000. The removal of the dummy gate stacks 220 may include one or more etching processes that are selective to the material in the dummy gate stacks 220. For example, the removal of the dummy gate stacks 220 may be performed using as a selective wet etch, a selective dry etch, or a combination thereof. After the removal of the dummy gate stacks 220, sidewalls of the channel layers 208 and sacrificial layers 206 in the channel regions 210C are exposed. Thereafter, the sacrificial layers 206 in the channel regions 210C are selectively removed to release the first nanostructures 2080 in the first region 1000 and the second nanostructures 2080 in the second region 2000. The first nanostructures 2080 in the first region 1000 and the second nanostructures 2080 in the second region 2000 may also be referred to as channel members. The selective removal of the sacrificial layers 206 may be implemented by selective dry etch, selective wet etch, or other selective etch processes. In some embodiments, the selective wet etching includes an APM etch (e.g., ammonia hydroxide-hydrogen peroxide-water mixture). In some other embodiments, the selective removal includes SiGe oxidation followed by a silicon germanium oxide removal. For example, the oxidation may be provided by ozone clean and then silicon germanium oxide removed by an etchant such as NH₄OH.

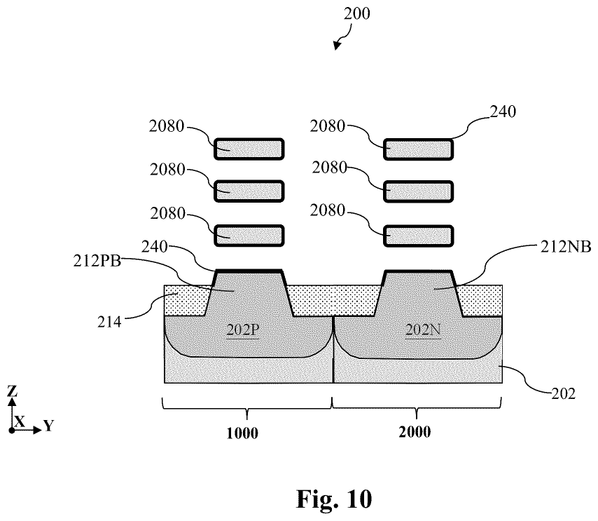

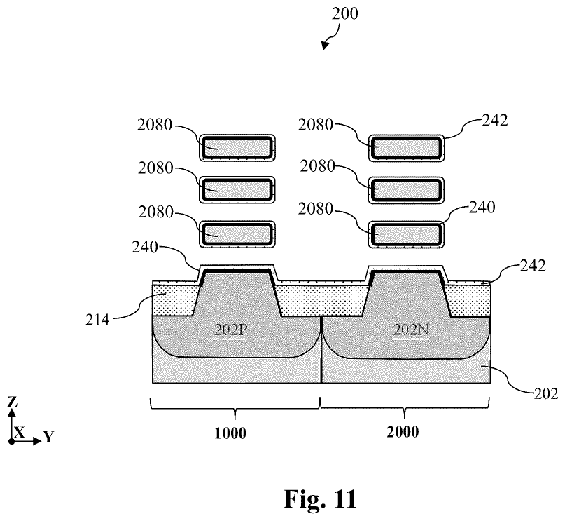

Referring to FIGS. 1 and 10, method 100 includes a block 104 where an interfacial layer 240 is formed over the first nanostructures 2080 and the second nanostructures 2080. As shown in FIG. 10, the first nanostructures 2080 are disposed over the first base fin 212PB in the first region 1000 and the second nanostructures 2080 are disposed over the second base fin 212NB in the second region 2000. Because the first base fin 212PB is patterned from the p-type well 202P, the first base fin 212PB includes the same composition with the p-type well 202P. Because the second base fin 212NB is patterned from the n-type well 202N, the second base fin 212NB includes the same composition with the n-type well 202N. In FIG. 10, the first region 1000 may be contiguous with the second region 2000. As a result, the p-type well 202P may interface the n-type well 202N. The interfacial layer 240 may include silicon oxide or silicon oxynitride, or other suitable material. In some embodiments, the interfacial layer 240 may be deposited over surfaces of the first nanostructures 2080, surfaces of the second nanostructures, top surfaces of the first base fin 212PB and the second base fin 212NB, and sidewalls of the portions of the first base fin 212PB and the second base fin 212NB above the isolation feature 214 using a suitable method, such as atomic layer deposition (ALD), chemical vapor deposition (CVD), ozone oxidation, thermal oxidation, or other suitable method. The interfacial layer 240 serves the function to control and reduce gate leakage current and improve interfacial adhesion between the gate dielectric layer 242 (shown in FIG. 11) and the nanostructures (including the first nanostructures 2080 in the first region 1000 and the second nanostructures 2080 in the second region 2000). In the depicted embodiments, the interfacial layer 240 is formed using thermal oxidation and the interfacial layer 240 is selectively deposited on semiconductor surfaces but not on dielectric surfaces, such as the top surfaces of the isolation feature 214.

Referring to FIGS. 1 and 11, method 100 includes a block 106 where a gate dielectric layer 242 is deposited over the interfacial layer 240. In some embodiments, the gate dielectric layer 242 is high-k dielectric layer as its dielectric constant is greater than that of silicon dioxide (~3.9). In some implementations, the gate dielectric layer 242 may include doped or undoped hafnium oxide (HfO₂), doped or undoped zirconium oxide (ZrO₂), doped or undoped titanium oxide (TiO₂), or doped or undoped aluminum oxide (Al₂O₃). For example, the gate dielectric layer 242 may include hafnium silicon oxide (HfSiO), hafnium silicon oxynitride (HfSiON), or hafnium aluminum oxide (HfAlO), hafnium tantalum oxide (HfTaO), Hafnium zirconium oxide (HfZrO), zirconium silicon oxide (ZrSiO₂), hafnium titanium oxide (HfTiO), or a combination thereof. Upon conclusion of operations at block 106, each of the first nanostructures 2080 in the first region 1000 and the second nanostructures 2080 in the second region 2000 is wrapped around by the interfacial layer 240 and the gate dielectric layer 242. Furthermore, as illustrated in FIG. 11, the deposition of the gate dielectric layer 242 may not be selective and the gate dielectric layer 242 may be deposited over the isolation feature 214.

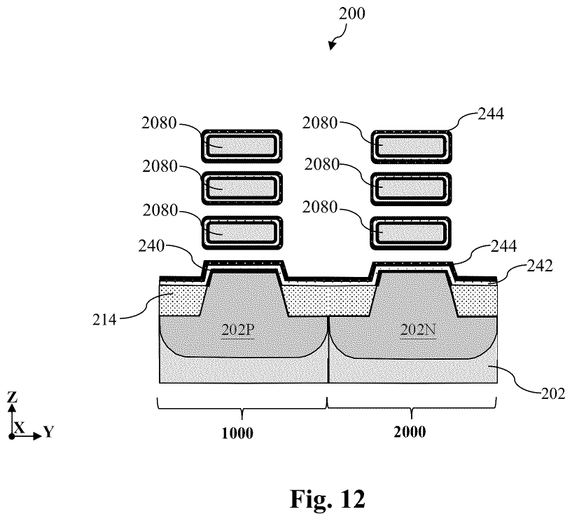

Referring to FIGS. 1 and 12, method 100 includes a block 108 where a first work function metal (WFM) layer 244 is deposited over the first region 1000 and the second region 2000. In some embodiments, the first WFM layer 244 may be a p-type WFM layer and may include titanium nitride (TiN), titanium silicon nitride (TiSiN), tantalum nitride (TaN), tungsten carbonitride (WCN), molybdenum (Mo), or other suitable p-type work function material. In one embodiment, the first WFM layer 244 includes titanium nitride (TiN). The first WFM layer 244 may be deposited using ALD at a temperature between about 350° C. and about 450° C. As show in FIG. 12, a thickness of the first WFM layer 244 is such that the spacing between two adjacent first nanostructures 2080 or second nanostructures 2080 is not completely filled. In some instances, a thickness of the first WFM layer 244 may be between about 7 Å and 13 Å. When the first WFM layer 244 is formed of a two-component material, such as titanium nitride, it has a grain size greater than 3.5 nm, such as between 3.5 nm and about 4.5 nm.

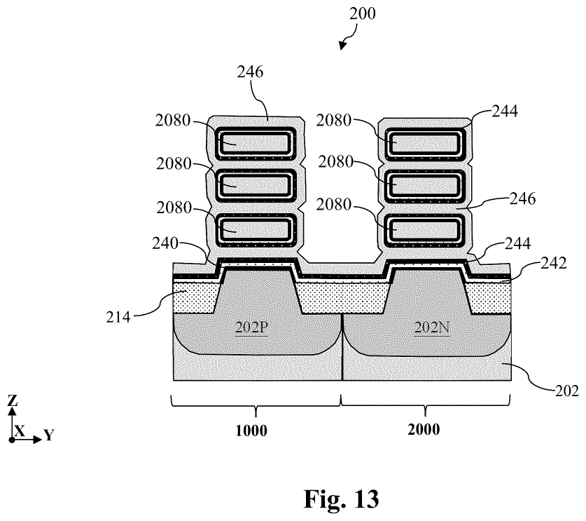

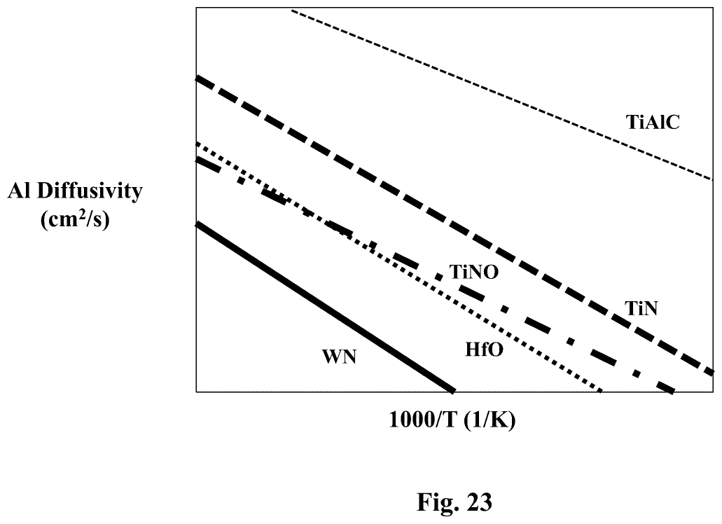

Referring to FIGS. 1 and 13, method 100 includes a block 110 where a diffusion blocking layer 246 is deposited over the first WFM layer 244. The diffusion blocking layer 246 functions to block or impede diffusion of impurities from a second WFM layer 250 into the first WFM layer 244. In some embodiments, the diffusion blocking layer 246 includes titanium (Ti), tungsten (W), and nitrogen (N) to block diffusion of aluminum (Al) from the second WFM layer 250 into the first WFM layer 244. As will be described below, the second WFM layer 250 includes aluminum (Al) and mya be referred to as an aluminum-containing layer. It has been observed that diffusion of aluminum (Al) into the first WFM layer 244 impacts performance of p-type GAA transistors. Particularly, diffusion of aluminum (Al) into the first WFM layer 244 may increase threshold voltage (Vt) of p-type GAA transistors. Reference is now made to FIG. 23, which illustrates diffusivity of aluminum (Al) within different materials, including titanium aluminum carbide (TiAlC), titanium nitride (TiN), titanium nitride oxide (TiNO), hafnium oxide (HfO), and tungsten nitride (WN) As shown in FIG. 23, The diffusivity of aluminum in titanium aluminum carbide (TiAlC) is the highest and the diffusivity of tungsten nitride (WN) in the lowest. The diffusivity of aluminum in titanium nitride (TiN) falls between its diffusivity in the titanium nitride (TiN) and that in the tungsten nitride (WN). While tungsten nitride (WN) possesses superior capability to block or slow down the diffusion of aluminum, tungsten nitride (WN) has a wide range of electrical conductivity. Experimental results indicate that a resistivity of an-deposited tungsten nitride (WN) may be greater than 10,000 μΩ/cm, which may be one to two orders of magnitude greater than a resistivity of titanium nitride (TiN). This means that when the diffusion blocking layer 246 is formed of tungsten nitride (WN) alone, the high resistivity of tungsten nitride may increase gate resistance, which may not be desirable in all applications.

According to embodiments of the present disclosure, the diffusion blocking layer 246 may be deposited using atomic layer deposition (ALD) at a temperature between about 350° C. and about 400° C. In some embodiments, the ALD process for the deposition of the diffusion blocking layer 246 includes use of a titanium containing precursor, a tungsten containing precursor, and nitrogen containing precursor. In these embodiments, the diffusion blocking layer 246 may include titanium (Ti), tungsten (W) and nitrogen (N). According to the present disclosure, the ALD deposition of the diffusion blocking layer 246 may include at least one tungsten nitride loop and at least one titanium nitride loop. In some implementations, a tungsten nitride ALD loop includes use of a tungsten-containing precursor, such as tungsten hexafluoride (WF₆) or tungsten hexacarbonyl (W(CO)₆), and a nitrogen-containing precursor, such as ammonia (NH₃). A titanium nitride ALD loop includes use of a titanium-containing precursor, such as TDMAT (Tetrakis(dimethylamino) titanium), titanium tetrachloride (TiCl₄), TDEAT (tetrakis(diethylamido) titanium), or TEMATi (tetrakis(ethylmethylamido) titanium) and a nitrogen-containing precursor, such as ammonia (NH₃). It is noted that each of the ALD loop also includes use of purge gas to remove excess precursors at each precursor cycle.

In terms of composition, the diffusion blocking layer 246 may include titanium tungsten nitride (TiWN) with a tungsten content between about 10% and about 70%. When the tungsten content is smaller than 10%, the diffusion blocking layer 246 may not satisfactorily block aluminum diffusion. When the tungsten content is greater than 70%, the diffusion blocking layer 246 may increase gate resistance and make it difficult to selectively remove the diffusion blocking layer 246 at block 112. In some instances, a resistivity of the diffusion blocking layer 246 may be between about 980 μΩ/cm and about 42,000 μΩ/cm. A grain size of the diffusion blocking layer 246 may be between about 2.85 nm and about 3.16 nm. A density of the diffusion blocking layer 246 may be between about 5.63 g/cm³ and about 9.2 g/cm³. In general, the diffusion blocking layer 246 has a greater aluminum diffusion blocking capability when its density is higher. Additionally, the diffusion blocking layer 246 has a greater aluminum diffusion blocking capability when its resistivity is higher. When the diffusion blocking layer 246 is formed of a three-component material, such as titanium tungsten nitride (TiWN), it has a grain size between 2.8 nm and about 3.2. It is noted that a grain size of the diffusion blocking layer 246 is smaller than that of the first WFM layer 244.

As shown in FIG. 13, the diffusion blocking layer 246 is deposited such that it wraps around each of the first nanostructures 2080 over the first region 1000 and each of the second nanostructures 20870 over the second region 2000.

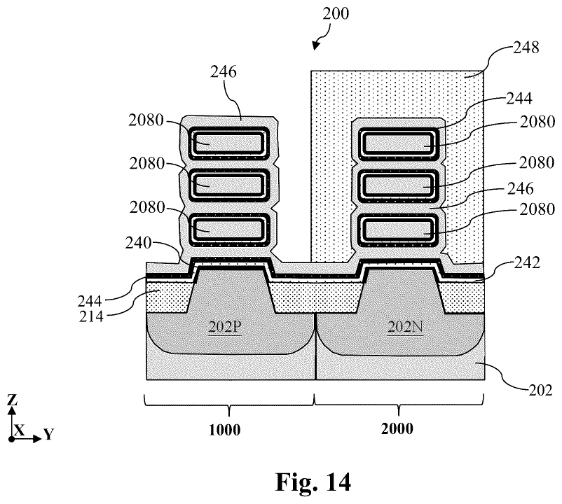

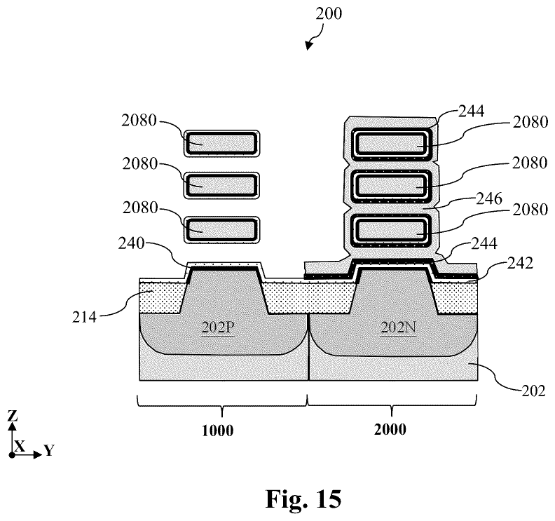

Referring to FIGS. 1, 14 and 15, method 100 includes a block 112 where the first WFM layer 244 and the diffusion blocking layer 246 over the first region 1000 is selectively removed. To selectively remove the diffusion blocking layer 246 and the first WFM layer 244 over the first region 1000, a bottom antireflective coating (BARC) layer 248 is formed over the second region 2000 while the first region 1000 is exposed. In an example process, a blanket BARC layer is deposited over the first region 1000 and the second region 2000, and then a photoresist layer is deposited over the blanket BARC layer. The photoresist layer is pre-baked, patterned by exposure to a patterned radiation passing through or reflected from a mask, post-baked, and developed in a developing process using a developer, to form a patterned photoresist layer. The patterned photoresist layer is used as an etch mask to pattern the blanket BARC layer to form the BARC layer 248, as shown in FIG. 14. With the BARC layer 248 covering the second region 2000, the diffusion blocking layer 246 and the first WFM layer 244 over the first region 1000 are removed. The removal of the diffusion blocking layer 246 and the first WFM layer 244 may be performed using one or more etching process. For example, the diffusion blocking layer 246 and the first WFM layer 244 may be removed using a wet etch process that includes a sulfuric acid hydrogen peroxide mixture (SPM), a mixture of ammonium hydroxide and hydrogen peroxide (SC1), or a mixture of hydrochloric acid and hydrogen peroxide (SC2), or a dry etch process that uses a plasma of a chlorine-containing gas (e.g., Cl₂ and/or BCl₃) and argon (Ar). After the diffusion blocking layer 246 and the first WFM layer 244 are removed from the first region 1000, the BARC layer 248 may be removed from the second region 2000 using ashing or a selective etching process, as illustrated in FIG. 15. The diffusion blocking layer 246 and the first WFM layer 244 may be regarded as a p-type WFM layer. In some instances, a total thickness of the diffusion blocking layer 246 and the first WFM layer 244 may be between about 10 Å and about 33 Å. In some embodiments, a thickness of the diffusion blocking layer 246 is greater than a thickness of the first WFM layer 244.

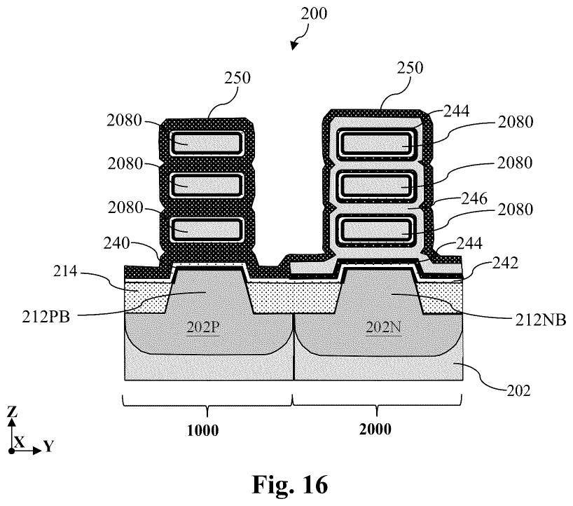

Referring to FIGS. 1 and 16, method 100 includes a block 114 where a second WFM layer 250 is deposited over the first region 1000 and the second region 2000. The second WFM layer 250 has a different conductivity type from the first WFM layer 244.

In some embodiments, the second WFM layer 250 is an n-type WFM layer while the first WFM layer 244 is a p-type WFM layer. The second WFM layer 250 includes aluminum and may be referred to as an aluminum-containing layer. In some embodiments, the second WFM layer 250 may include titanium aluminum (TiAl), titanium aluminum carbide (TiAlC), tantalum aluminum (TaAl), tantalum aluminum carbide (TaAlC), titanium aluminum nitride (TiAlN), or a combination thereof. In one embodiment, the second WFM layer 250 includes titanium aluminum carbide (TiAlC). The second WFM layer 250 may be deposited using ALD at a temperature between about 350° C. and about 380° C. As show in FIG. 16, due to the presence of the diffusion blocking layer 246 over the second region 2000, the second WFM layer 250 is deposited over the diffusion blocking layer 246 and no part of the second WFM layer 250 extends vertically between two adjacent nanostructures 2080 or vertical between a top surface of the second base fin 212NM and a bottom surface of the bottommost nanostructure 2080. Over the first region 1000, the second WFM layer 250 wraps around each of the nanostructures 2080. That is, the second WFM layer 250 extends between the spacing between two adjacent first nanostructures 2080 in the first region 1000 and between a top surface of the first base fin 212PM and a bottom surface of the bottommost nanostructure over the first region 1000. In some instances, a thickness of the second WFM layer 250 may between about 10 Å and about 33 Å. When the second WFM layer 250 is formed of a three-component material, such as titanium aluminum carbide (TiAlC), it has a grain size between 2.4 nm and about 2.8. It is noted that a grain size of the second WFM layer 250 is smaller than that of the first WFM layer 244 or that of the second WFM layer 246.

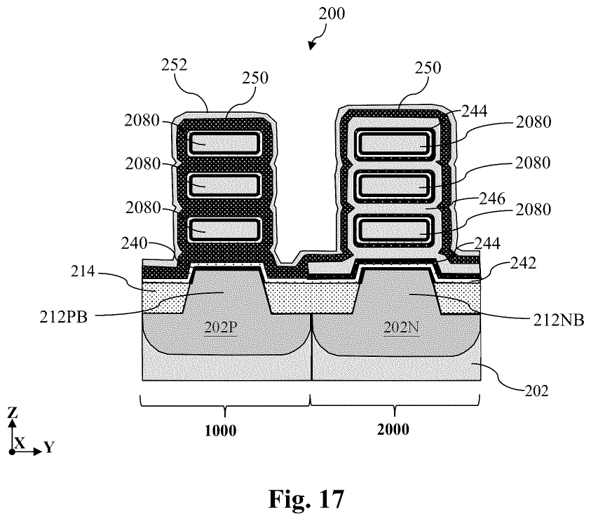

Referring to FIGS. 1 and 17, method 100 includes a block 116 where a protective layer 252 is deposited over the second WFM layer 250. At block 116, the protective layer 252 is deposited over the second WFM layer 250 and functions to prevent the second WFM layer 250 from being oxidized. The protective layer 252 may include a titanium-based material. In some embodiments, the protective layer 252 may include titanium nitride (TiN) and is formed in-situ after the second WFM layer 250 is deposited. This prevents oxygen in the ambient air from coming in contact with the second WFM layer 250 when the vacuum is broken. In some embodiments, the protective layer 252 may be formed by ALD. As shown in FIG. 17, because the spaces between the first nanostructures 2080 are filled with the second WFM layer 250 and the spaces between the second nanostructures 2080 are filled with the diffusion blocking layer 246, the protective layer 252 does not extend between two adjacent first nanostructures 2080 or two adjacent second nanostructures 2080. In some instances, the protective layer 252 includes a thickness between about 8 Å and about 20 Å.

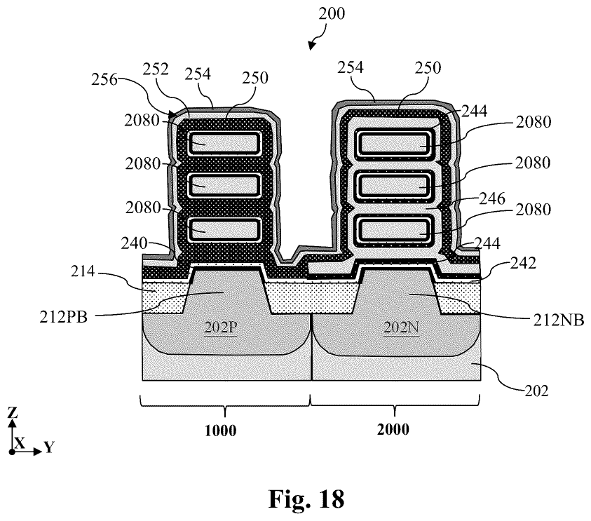

Referring to FIGS. 1 and 18, method 100 includes a block 118 where a semiconductor cap layer 254 is deposited over the protective layer 252. The semiconductor cap layer 254 may include silicon (Si) and functions to prevent the protective layer 252 from being oxidized during subsequent fabrication processes. In some embodiments, the semiconductor cap layer 254 may be deposited using ALD and a silicon-containing precursor, such as silane (SiH₄) or disilane (Si₂H₆). In one embodiment, the semiconductor cap layer 254 is deposited using disilane as a precursor. In some instances, the semiconductor cap layer 254 may have a thickness between about 5 Å and about 15 Å. In some implementations, a precursor structure or a wafer having structures formed at blocks 102-118 is removed from a vacuum chamber after the deposition of the semiconductor cap layer 254. The exposure to ambient air may form a thin silicon oxide layer on the surface of the semiconductor cap layer 254. This thin silicon oxide layer may not be removed before deposition of further layers.

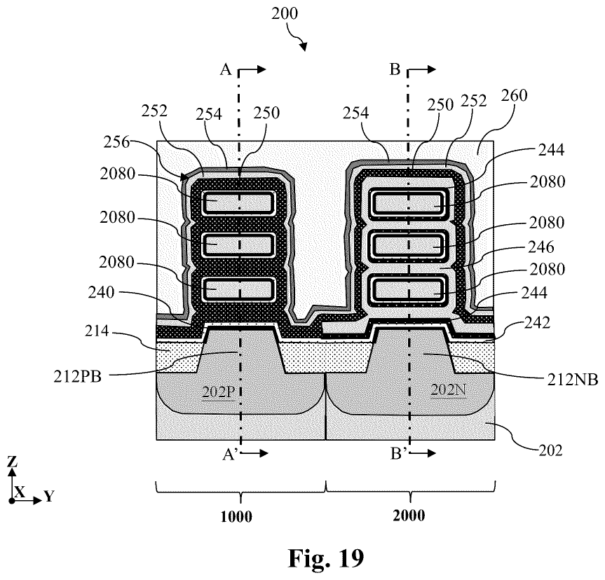

Referring to FIGS. 1 and 19, method 100 includes a block 120 where a metal fill layer 260 is deposited over the semiconductor cap layer 254. While not explicitly shown in figures, a glue layer may be deposited over the semiconductor cap layer 254 to improve adhesion of the metal fill layer 260. The glue layer may include titanium nitride. In some embodiments, the metal fill layer 260 may include tungsten (W) and may be deposited using ALD or CVD. Reference is made to FIG. 19. The deposition of the semiconductor cap layer 254, the glue layer and the metal fill layer 260 may cause the semiconductor cap layer 254 to react with the protective layer 252 at an interface of these two layers to form a compound protective layer 256, which may include silicon titanium nitride (SiTiN).

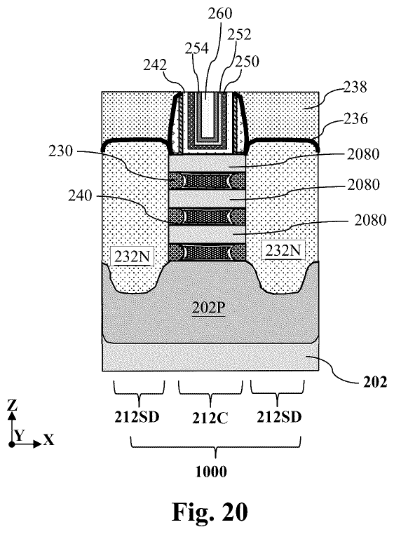

FIG. 20 illustrates a fragmentary cross-sectional view along section A-A in FIG. 19. Line A-A′ cuts lengthwise through the first nanostructures 2080 in the first region 1000. As shown in FIG. 20, each of the first nanostructures 2080 extends between two first source/drain features 232N along the X direction. The interfacial layer 240, the gate dielectric layer 242, and the second WFM layer 250 wrap around each of the first nanostructures 2080 in the first region 1000. The protective layer 252, the semiconductor cap layer 254, and the metal fill layer 260 are disposed over the first nanostructures 2080 but do not extend between two adjacent ones of the first nanostructures 2080. The interfacial layer 240, the gate dielectric layer 242, the second WFM layer 250, the protective layer 252, the semiconductor cap layer 254, and the metal fill layer 260 may be regarded as an n-type gate structure.

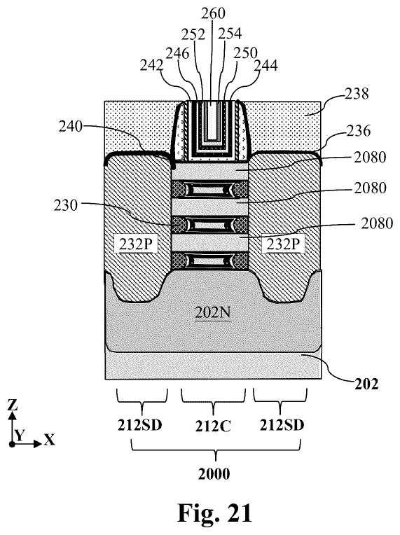

FIG. 21 illustrates a fragmentary cross-sectional view along section B-B in FIG. 19. Line B-B′ cuts lengthwise through the second nanostructures 2080 in the second region 2000. As shown in FIG. 21, each of the second nanostructures 2080 extends between two second source/drain features 232P along the X direction. The interfacial layer 240, the gate dielectric layer 242, the first WFM layer 244, and the diffusion blocking layer 246 wrap around each of the second nanostructures 2080 in the second region 2000. The second WFM layer 250, the protective layer 252, the semiconductor cap layer 254, and the metal fill layer 260 are disposed over the second nanostructures 2080 but do not extend between two adjacent ones of the second nanostructures 2080. The interfacial layer 240, the gate dielectric layer 242, the first WFM layer 244, the diffusion blocking layer 246, the second WFM layer 250, the protective layer 252, the semiconductor cap layer 254, and the metal fill layer 260 may be regarded as a p-type gate structure. Because the n-type gate structure and the p-type gate structure share all these layers except for the diffusion blocking layer 246 and the first WFM layer 244, they may be collectively referred to as a gate structure or a common gate structure.

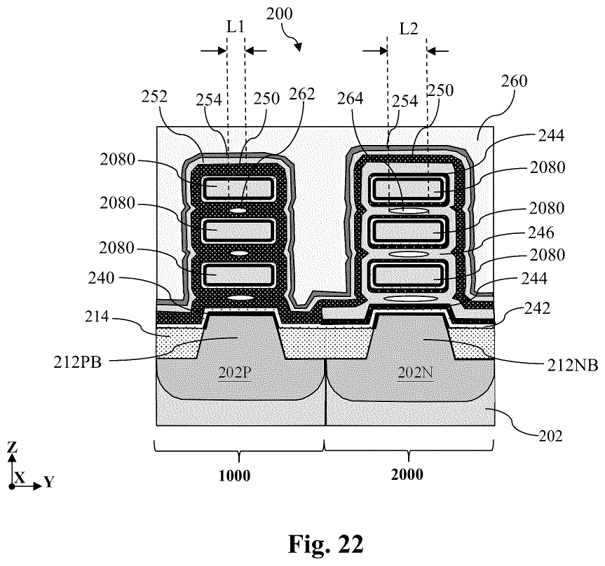

FIG. 22 illustrates a semiconductor structure 200 formed using method 100. The semiconductor structure 200 in FIG. 22 is substantially similar to the semiconductor structure in FIG. 19, except that the second WFM layer 250 over the first region 1000 includes first seams 262 and the diffusion blocking layer 246 over the second region 2000 includes second seams 264. The first seams 262 and the second seams 264 are formed when the layer filling the space between two adjacent first nanostructures 2080 or two adjacent second nanostructures 2080 merge prematurely before it fills the space. Indeed, the diffusion blocking layer 246 filling the spaces between the first nanostructures 2080 may prematurely merge, thereby forming the first seams 262 in the diffusion blocking layer 246. The second WFM layer 250 filling the spaces between the second nanostructures 2080 may prematurely merge, thereby forming the second seams 264 in the diffusion blocking layer 246. As described above, a grain size of the second WFM layer 250 is smaller than a grain size of the diffusion blocking layer 246. It is observed that the smaller grain size allows of the second WFM layer 250 to have better hole-filling property, which leads to a smaller seam length along. On average, a first average length L1 of the first seams 262 along the Y direction is smaller than a second average length L2 of the second seams 264 along the Y direction. It is also noted that the seams closer the first base fin 212PB and the second base fin 212NB tend to have greater lengths along the Y direction.

The present disclosure provides embodiments of processes for forming a gate structure of a multi-gate device. In one embodiment, a method is provided. The method includes receiving a precursor structure that includes a substrate, a first plurality of nanostructures over a first region of the substrate, a second plurality of nanostructures over a second region of the substrate, and an isolation feature over the substrate, depositing a gate dielectric layer over surfaces of each of the first plurality of nanostructures and each of the second plurality of nanostructures, depositing a first work function metal layer over the first plurality of nanostructures over the first region and the second plurality of nanostructures over the second region, depositing a diffusion blocking layer over the first work function metal layer such that the diffusion blocking layer wraps around each of the first plurality of nanostructures over the first region and each of the second plurality of nanostructures over the second region, selectively removing the diffusion blocking layer and the first work function metal layer from the first plurality of nanostructures over the first region, after the selectively removing, depositing a second work function metal layer over the first plurality of nanostructures over the first region and the second plurality of nanostructures over the second region, and depositing a metal fill layer over the second work function metal layer. A portion of the gate dielectric layer extends along a top surface of the isolation feature.

In some embodiments, the diffusion blocking layer includes TiWN. In some implementations, the first work function metal layer includes a p-type work function metal layer. In some embodiments, the second work function metal layer includes an n-type work function metal layer. In some embodiments, the second work function metal layer includes aluminum. In some instances, the first work function metal layer includes titanium nitride. In some embodiments, a total thickness of the first work function metal layer and the diffusion blocking layer is between about 10 Å and about 33 Å. In some implementations, the depositing of the diffusion blocking layer includes an atomic layer deposition (ALD) process and the ALD process includes at least one tungsten nitride loop and at least one titanium nitride loop. In some instances, a tungsten content in the diffusion blocking layer is between about 10% and about 70%.

In another embodiment, a method is provided. The method includes receiving a precursor structure that includes a substrate, a first base fin and a second base fin over the substrate, an isolation structure over the substrate and disposed between the first base fin and the second base fin, a first nanostructures over the first fin, and a second nanostructures over the base fin, depositing a gate dielectric layer over the first base fin, the first nanostructures, the second base fin, the second nanostructures, and the isolation structure, depositing a p-type work function metal layer over the first nanostructures and the second nanostructures, depositing a diffusion blocking layer over the p-type work function metal layer such that the diffusion blocking layer wraps around each of the first nanostructures and each of the second nanostructures, selectively removing the diffusion blocking layer and the p-type work function metal layer from the first nanostructures, after the selectively removing, depositing an n-type work function metal layer over the first nanostructures and the second nanostructures, depositing a protective layer over the n-type work function metal layer, and depositing a metal fill layer over the protective layer. The protective layer includes a titanium-based material. A dielectric constant of the gate dielectric layer is greater than a dielectric constant of the isolation structure.

In some embodiments, the p-type work function metal layer includes titanium nitride and the n-type work function metal layer includes titanium aluminum nitride. In some implementations, the protective layer includes a thickness between about 8 Å and about 20 Å. In some embodiments, a tungsten content in the diffusion blocking layer is between about 10% and about 70%. In some instances, a thickness of the n-type work function metal layer includes a thickness between about 10 Å and about 33 Å. In some embodiments, the selectively removing includes removing the p-type work function metal layer from between two adjacent ones of the first nanostructures. In some embodiments, the depositing of the diffusion blocking layer includes an atomic layer deposition (ALD) process and the ALD process includes at least one tungsten nitride loop and at least one titanium nitride loop.

In a further embodiment, a method is provided. The method includes a first base fin and a second base fin over a substrate, an isolation feature over the substrate and interfacing sidewalls of the first base fin and the second base fin, a first plurality of nanostructures disposed over the first base fin, a second plurality of nanostructures disposed over the second base fin, a gate dielectric layer wrapping around each of the first plurality of nanostructures, each of the second plurality of nanostructures, the gate dielectric layer being disposed over top surfaces of the first base fin, the second base fin, and the isolation feature, a first work function layer wrapping around each of the second plurality of nanostructures and disposed over the second base fin, a diffusion blocking layer wrapping around each of the second plurality of nanostructures, a second work function layer wrapping around each of the first plurality of nanostructures over the first base fin and disposed over the diffusion blocking layer over the second base fin, and a protective layer over the second work function layer over the first base fin and the second base fin. The diffusion blocking layer includes titanium tungsten nitride.

In some embodiments, the protective layer includes titanium silicon nitride. In some implementations, a total thickness of the first work function layer and the diffusion blocking layer is between about 10 Å and about 33 Å. In some embodiments, the diffusion blocking layer among the second plurality of nanostructures includes a seam.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure. For example, by implementing different thicknesses for the bit-line conductor and word line conductor, one can achieve different resistances for the conductors. However, other techniques to vary the resistances of the metal conductors may also be utilized as well.

What is claimed is:

1. A method, comprising:
receiving a precursor structure comprising:
a substrate,
a first plurality of nanostructures over a first region of the substrate,
a second plurality of nanostructures over a second region of the substrate, and,
an isolation feature over the substrate;
depositing a gate dielectric layer over surfaces of the first plurality of nanostructures and the second plurality of nanostructures;
depositing a first work function metal layer over the first plurality of nanostructures over the first region and the second plurality of nanostructures over the second region;
depositing a diffusion blocking layer over the first work function metal layer such that the diffusion blocking layer wraps around the first plurality of nanostructures over the first region and the second plurality of nanostructures over the second region;
selectively removing the diffusion blocking layer and the first work function metal layer from the first plurality of nanostructures over the first region;
after the selectively removing, depositing a second work function metal layer over the first plurality of nanostructures over the first region and the second plurality of nanostructures over the second region; and
depositing a metal fill layer over the second work function metal layer,
wherein a portion of the gate dielectric layer extends along a top surface of the isolation feature.

2. The method of claim 1, wherein the diffusion blocking layer comprises TiWN.

3. The method of claim 1, wherein the first work function metal layer comprises a p-type work function metal layer.

4. The method of claim 1, wherein the second work function metal layer comprises an n-type work function metal layer.

5. The method of claim 1, wherein the second work function metal layer comprises aluminum.

6. The method of claim 1, wherein the first work function metal layer comprises titanium nitride.

7. The method of claim 1, wherein a total thickness of the first work function metal layer and the diffusion blocking layer is between about 10 Å and about 33 Å.

8. The method of claim 1,
wherein the depositing of the diffusion blocking layer comprises an atomic layer deposition (ALD) process,
wherein the ALD process comprises at least one tungsten nitride loop and at least one titanium nitride loop.

9. The method of claim 1, wherein a tungsten content in the diffusion blocking layer is between about 10% and about 70%.

10. A method, comprising:
receiving a precursor structure comprising:
a substrate,
a first base fin and a second base fin over the substrate,
an isolation structure over the substrate and disposed between the first base fin and the second base fin,
a first nanostructures over the first fin, and
a second nanostructures over the base fin;
depositing a gate dielectric layer over the first base fin, the first nanostructures, the second base fin, the second nanostructures, and the isolation structure;
depositing a p-type work function metal layer over the first nanostructures and the second nanostructures;
depositing a diffusion blocking layer over the p-type work function metal layer such that the diffusion blocking layer wraps around the first nanostructures and the second nanostructures;
selectively removing the diffusion blocking layer and the p-type work function metal layer from the first nanostructures;
after the selectively removing, depositing an n-type work function metal layer over the first nanostructures and the second nanostructures;
depositing a protective layer over the n-type work function metal layer; and
depositing a metal fill layer over the protective layer,
wherein the protective layer comprises a titanium-based material,
wherein a dielectric constant of the gate dielectric layer is greater than a dielectric constant of the isolation structure.

11. The method of claim 10,
wherein the p-type work function metal layer comprises titanium nitride,
wherein the n-type work function metal layer comprises titanium aluminum nitride.

12. The method of claim 10, wherein the protective layer comprises a thickness between about 8 Å and about 20 Å.

13. The method of claim 10, wherein a tungsten content in the diffusion blocking layer is between about 10% and about 70%.

14. The method of claim 10, wherein a thickness of the n-type work function metal layer comprises a thickness between about 10 Å and about 33 Å.

15. The method of claim 10, wherein the selectively removing comprises removing the p-type work function metal layer from between two adjacent ones of the first nanostructures.

16. The method of claim 10,
wherein the depositing of the diffusion blocking layer comprises an atomic layer deposition (ALD) process,
wherein the ALD process includes at least one tungsten nitride loop and at least one titanium nitride loop.

17. A semiconductor structure, comprising:
a first base fin and a second base fin over a substrate;
an isolation feature over the substrate and interfacing sidewalls of the first base fin and the second base fin;
a first plurality of nanostructures disposed over the first base fin;
a second plurality of nanostructures disposed over the second base fin;
a gate dielectric layer wrapping around the first plurality of nanostructures, the second plurality of nanostructures, the gate dielectric layer being disposed over top surfaces of the first base fin, the second base fin, and the isolation feature;
a first work function layer wrapping around the second plurality of nanostructures and disposed over the second base fin;
a blocking layer wrapping around the second plurality of diffusion nanostructures;
a second work function layer wrapping around the first plurality of nanostructures over the first base fin and disposed over the diffusion blocking layer over the second base fin; and
a protective layer over the second work function layer over the first base fin and the second base fin,
wherein the diffusion blocking layer comprises titanium tungsten nitride.

18. The semiconductor structure of claim 17, wherein the protective layer comprises titanium silicon nitride.

19. The semiconductor structure of claim 17, wherein a total thickness of the first work function layer and the diffusion blocking layer is between about 10 Å and about 33 Å.

20. The semiconductor structure of claim 17, wherein the diffusion blocking layer among the second plurality of nanostructures comprises a seam.
